(19) United States
(12) Patent Application Publication
(10) Pub. No.: US 2026/0082642 A1
(43) Pub. Date: Mar. 19, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Raita KOTANI, Tatsuno Hyogo (JP)

(21) Appl. No.: 18/958,544

(22) Filed: Nov. 25, 2024

(30) Foreign Application Priority Data
Sep. 19, 2024 (JP) 2024-162671

(51) Int. Cl. H10D 12/00; H10D 62/10

(52) U.S. Cl. CPC H10D 62/107; H10D 12/411; H10D 62/124

(57) ABSTRACT

A semiconductor device includes a first semiconductor region including a central part and a termination region; a second semiconductor region located at a lower part of the first semiconductor region at the central part; a third semiconductor region located at an upper part of the first semiconductor region at the central part; a first electrode located at a lower surface of the second semiconductor region at the central part; a second electrode located at an upper surface of the third semiconductor region; a ring-shaped region located in the termination region at the upper part of the first semiconductor region, the ring-shaped region surrounding the third semiconductor region; and a fourth semiconductor region located at a side surface of the first semiconductor region.

### CROSS-REFERENCE TO RELATED APPLICATION

This application is based upon and claims the benefit of priority from Japanese Patent Application No.2024-162671, filed on Sep. 19, 2024; the entire contents of which are incorporated herein by reference.

### FIELD

Embodiments described herein relate generally to a semiconductor device.

### BACKGROUND

A semiconductor device such as a diode, a metal-oxide-semiconductor field-effect transistor (MOSFET), an insulated gate bipolar transistor (IGBT), or the like is used in applications such as power conversion, etc. Such a semiconductor device includes a termination region to maintain the breakdown voltage.

### BRIEF DESCRIPTION OF THE DRAWINGS

FIG. 1 is a plan view illustrating a semiconductor device according to a first embodiment;

FIG. 2 is a II-II cross-sectional view of FIG. 1;

FIGS. 3A to 3C are schematic views showing operations of the semiconductor device;

FIG. 4 is a cross-sectional view of a semiconductor device according to a modification 1;

FIG. 5 is a cross-sectional view of a semiconductor device according to a modification 2;

FIG. 6 is a graph showing a simulation result of a semiconductor device as an example; and

FIG. 7 is a graph showing a simulation result of a semiconductor device as a reference example.

### DETAILED DESCRIPTION

According to one embodiment, a semiconductor device includes a first semiconductor region including a central part and a termination region, the termination region surrounding the central part, the first semiconductor region being of a first conductivity type; a second semiconductor region located at a lower part of the first semiconductor region at the central part, the second semiconductor region being of the first conductivity type, the second semiconductor region having a higher impurity concentration than the first semiconductor region; a third semiconductor region located at an upper part of the first semiconductor region at the central part, the third semiconductor region being of a second conductivity type; a first electrode located at a lower surface of the second semiconductor region at the central part, the first electrode being electrically connected with the second semiconductor region; a second electrode located at an upper surface of the third semiconductor region, the second electrode being electrically connected with the third semiconductor region; a ring-shaped region located in the termination region at the upper part of the first semiconductor region, the ring-shaped region surrounding the third semiconductor region, the ring-shaped region being of the second conductivity type; and a fourth semiconductor region located at a side surface of the first semiconductor region, the fourth semiconductor region being of the second conductivity type.

Embodiments of the invention will now be described with reference to the drawings.

The drawings are schematic or conceptual; and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to a drawing thereinabove are marked with like reference numerals, and a detailed description is omitted as appropriate.

In the following description and drawings, the notations of n⁺, n, n⁻, p⁺, p, and p⁻ indicate relative levels of the impurity concentrations. Specifically, a notation marked with “+” indicates that the impurity concentration is relatively higher than that of a notation not marked with either “+” or “−”; and a notation marked with “−” indicates that the impurity concentration is relatively lower than that of a notation without any mark. When both a p-type impurity and an n-type impurity are included in each region, these notations indicate relative levels of the net impurity concentrations after the impurities compensate each other.

### First Embodiment

According to the embodiments below, each embodiment may be implemented by inverting the p-type and the n-type of each semiconductor region.

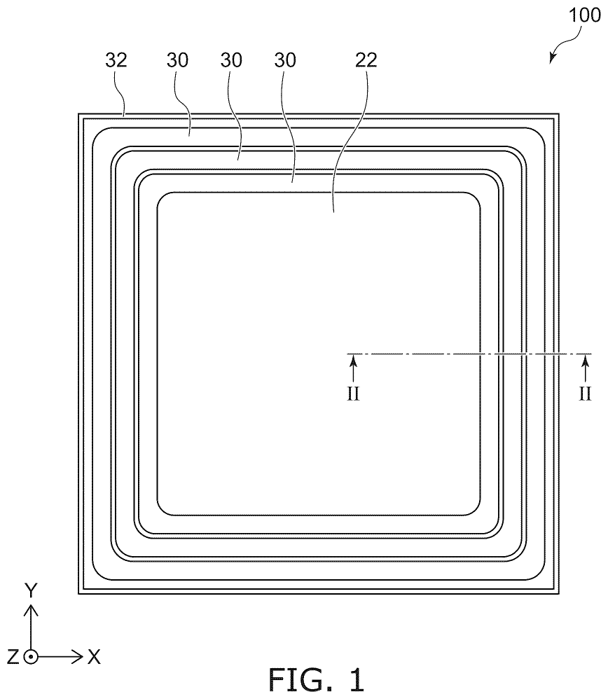

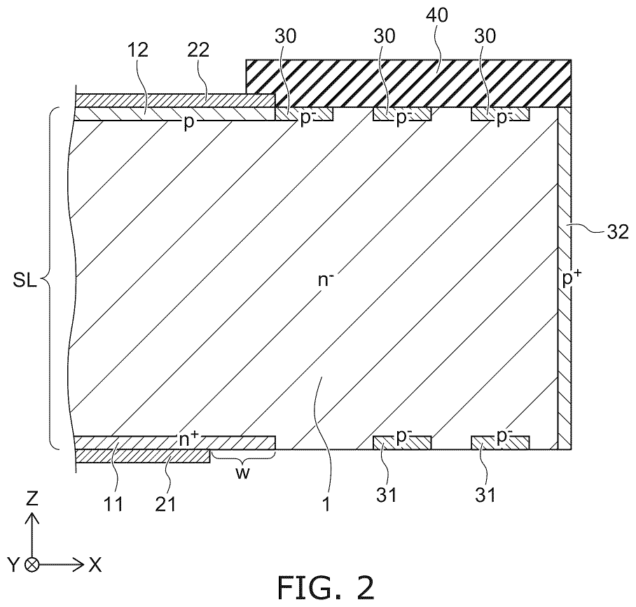

FIG. 1 is a plan view illustrating a semiconductor device according to a first embodiment. An insulating part 40 is not illustrated in FIG. 1. FIG. 2 is a II-II cross-sectional view of FIG. 1.

As an example, the semiconductor device 100 according to the first embodiment is a diode. As illustrated in FIGS. 1 and 2, the semiconductor device 100 includes a semiconductor layer SL, a lower electrode 21 as a first electrode, an upper electrode 22 as a second electrode, and the insulating part 40.

An XYZ orthogonal coordinate system is used in the description of embodiments. Specifically, the direction from the lower electrode 21 toward the upper electrode 22 is taken as a Z-direction. Two mutually-orthogonal directions perpendicular to the Z-direction are taken as an X-direction and a Y-direction. A direction from the center toward the outer perimeter of the semiconductor device 100 when viewed in plan is called a radial direction. In the description, the direction from the lower electrode 21 toward the upper electrode 22 is called “up”, and the opposite direction is called “down”. These directions are based on the relative positional relationship between the lower electrode 21 and the upper electrode 22 and are independent of the direction of gravity.

As shown in FIG. 2, the semiconductor layer SL includes a first semiconductor region 1 of a first conductivity type (e.g., the n⁻ type), a second semiconductor region 11 (as an example, an n-contact layer) that is of the first conductivity type (e.g., the n⁺-type) and has a higher impurity concentration than the first semiconductor region 1, a third semiconductor region 12 of a second conductivity type (e.g., the p-type), a ring-shaped region 30 that is of the second conductivity type (e.g., the p⁻-type) and has, for example, a lower impurity concentration than the third semiconductor region 12, a second ring-shaped region 31 that is of the second conductivity type (e.g., the p⁻-type) and has, for example, a lower impurity concentration than the third semiconductor region, and a fourth semiconductor region 32 that is of the second conductivity type (e.g., the p⁺-type) and has a higher impurity concentration than the third semiconductor region 12.

The second semiconductor region 11 is located at the lower part of the first semiconductor region 1 at the central part, which does not include the termination region when viewed in plan. The lower electrode 21 that is electrically connected with the second semiconductor region 11 is located at the lower surface of the second semiconductor region 11. The lower electrode 21 is located at the central part of the semiconductor device 100 when viewed in plan. Favorably, the lower electrode 21 is shorter in the radial direction than the second semiconductor region 11. In the example shown in FIG. 2, the radial-direction length of the lower electrode 21 is less than the radial-direction length of the second semiconductor region 11 by a length W. As a result, a voltage that is generated inside the first semiconductor region 1 can be prevented from being applied to the lower electrode 21.

The third semiconductor region 12 is located at the upper part of the first semiconductor region 1 at the central part, which does not include the termination region when viewed in plan. The upper electrode 22 that is electrically connected with the third semiconductor region 12 is located at the upper surface of the third semiconductor region 12. The upper electrode 22 is located at the central part of the semiconductor device 100 when viewed in plan.

The multiple ring-shaped regions 30 that surround the third semiconductor region 12 are located in the termination region at the upper part of the first semiconductor region 1. As shown in FIG. 1, the multiple ring-shaped regions 30 have ring shapes in the termination region of the semiconductor device 100 when viewed in plan with prescribed spacings respectively interposed. The number of the multiple ring-shaped regions 30 is designed appropriately according to the desired breakdown voltage of the semiconductor device 100.

As an example, the insulating part 40 is located on a portion of the upper electrode 22 and on the upper surface of the peripheral part (the termination region) of the semiconductor device 100. Therefore, the insulating part 40 seals the upper surface of the termination region of the semiconductor device 100. The insulating part 40 covers the ring-shaped region 30. On the other hand, the upper surface of the central part of the upper electrode 22 is not covered with the insulating part 40 and is externally exposed.

The fourth semiconductor region 32 is continuous over the side surface of the first semiconductor region 1. The fourth semiconductor region 32 is continuous between the upper surface and the lower surface of the termination region. As shown in FIG. 1, the fourth semiconductor region 32 is located at the outer edge of the semiconductor device 100 when viewed in plan.

The multiple second ring-shaped regions 31 surround the second semiconductor region 11 in the termination region at the lower surface of the first semiconductor region 1. The multiple second ring-shaped regions 31 have ring shapes in the termination region of the semiconductor device 100 when viewed in plan with a prescribed spacing respectively interposed. The number of the multiple second ring-shaped regions 31 is designed appropriately according to the desired breakdown voltage of the semiconductor device 100, and is favorably less than the number of the ring-shaped regions 30.

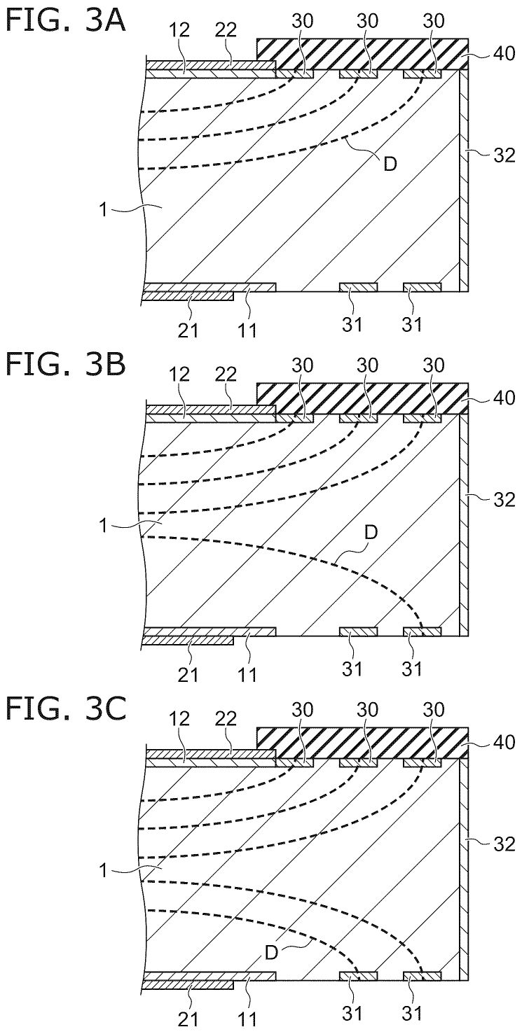

Operations of the first embodiment will now be described with reference to FIGS. 3A to 3C.

FIGS. 3A to 3C are schematic views showing operations of the semiconductor device.

Operations of the semiconductor device 100 will now be described. A forward voltage is applied to the p-n junction surface between the first semiconductor region 1 and the third semiconductor region 12 when a positive voltage with respect to the lower electrode 21 is applied to the upper electrode 22. As a result, the semiconductor device 100 is switched to the on-state; and a current flows from the upper electrode 22 toward the lower electrode 21.

Subsequently, when a positive voltage with respect to the upper electrode 22 is applied to the lower electrode 21, the flow of the current stops, and the semiconductor device 100 is switched from the on-state to the off-state. A reverse voltage is applied to the p-n junction surface between the first semiconductor region 1 and the third semiconductor region 12. As shown in FIG. 3A, the application of the reverse voltage causes a depletion layer edge D to spread toward the termination region in a downwardly convex shape from the p-n junction surface between the first semiconductor region 1 and the third semiconductor region 12.

The depletion layer edge D does not easily penetrate to the fourth semiconductor region 32, which has a high impurity concentration and is located at the side surface of the semiconductor device 100. On the other hand, because a region that is undepleted remains at the central part of the first semiconductor region 1, the depletion layer edge D spreads downward in an upwardly convex shape as shown in FIG. 3B. Furthermore, as shown in FIG. 3C, the depletion layer edge D spreads in the direction of the second semiconductor region 11, that is, toward the central part. Thus, because the fourth semiconductor region 32 that has a high impurity concentration is located at the side surface of the semiconductor device 100, the spreading of the depletion layer in the radial direction can be suppressed, and the breakdown voltage can be maintained with a smaller termination region.

Examples of the materials of the components of the semiconductor device 100 will now be described.

The first semiconductor region 1, the second semiconductor region 11, the third semiconductor region 12, the ring-shaped region 30, the second ring-shaped region 31, and the fourth semiconductor region 32 include silicon, silicon carbide, gallium nitride, or gallium arsenide as a semiconductor material. When silicon is used as the semiconductor material, arsenic, phosphorus, or antimony can be used as an n-type impurity. Boron can be used as a p-type impurity. The lower electrode 21 and the upper electrode 22 include a metal such as aluminum, copper, etc. The insulating part 40 includes an insulating resin material such as polyimide, etc.

### Modification 1

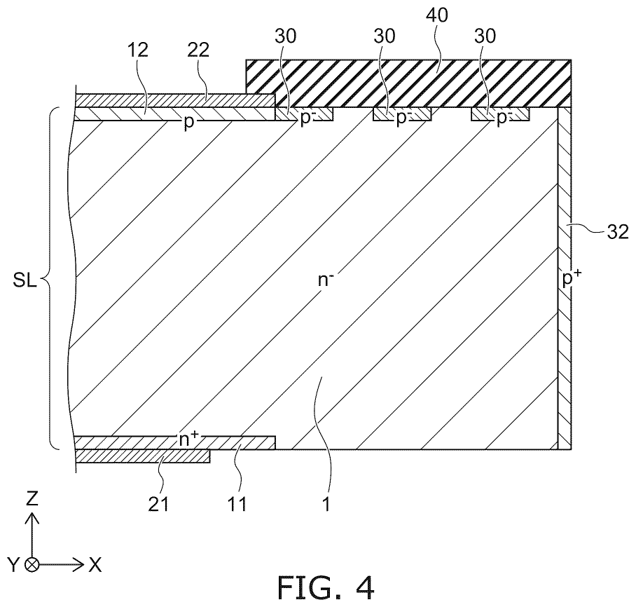

A modification 1 of the semiconductor device 100 will now be described with reference to FIG. 4.

FIG. 4 is a cross-sectional view of the semiconductor device 100 according to the modification 1.

According to the modification 1 as shown in FIG. 4, the second ring-shaped region 31 is not provided in the termination region at the lower surface of the first semiconductor region 1. By such a configuration as well, by providing the fourth semiconductor region 32 at the side surface of the first semiconductor region 1, the spreading in the radial direction of the depletion layer edge D can be suppressed similarly to the embodiment above, and the breakdown voltage can be maintained with a smaller termination region.

### Modification 2

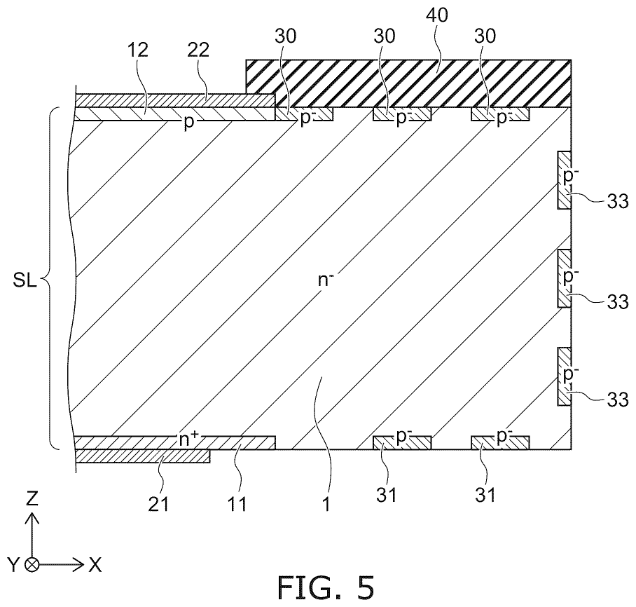

A modification 2 of the semiconductor device 100 will now be described with reference to FIG. 5.

FIG. 5 is a cross-sectional view of the semiconductor device according to the modification 2.

According to the modification 2 as shown in FIG. 5, a fifth semiconductor region 33 that is of the second conductivity type and has a lower impurity concentration than the third semiconductor region 12 is discontinuous at the side surface of the first semiconductor region 1. By such a configuration as well, the fifth semiconductor region 33 that is discontinuous at the side surface of the first semiconductor region 1 functions as an electric field relaxation layer, and so the breakdown voltage can be maintained with a smaller termination region.

### EXAMPLES

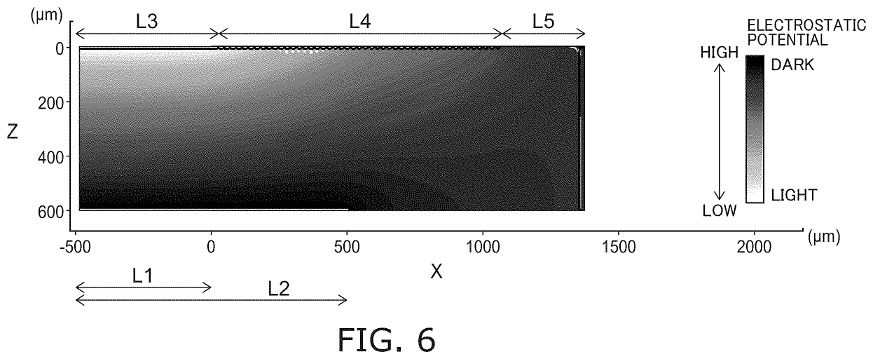

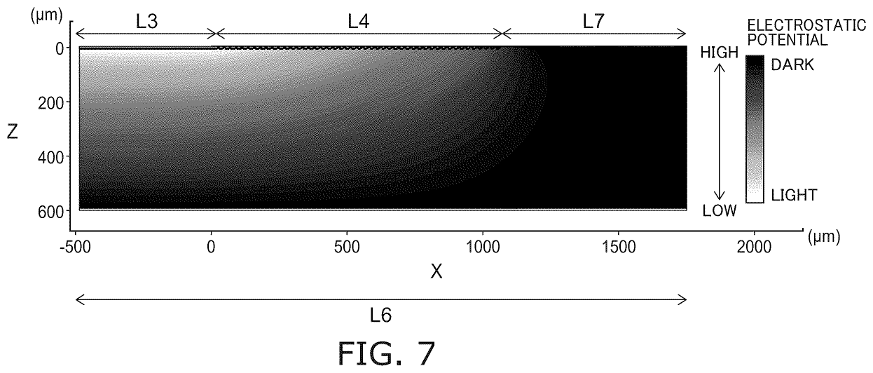

An example of the semiconductor device 100 and a reference example will now be described with reference to FIGS. 6 and 7.

FIG. 6 is a graph showing a simulation result of the semiconductor device 100 as an example.

FIG. 7 is a graph showing a simulation result of a semiconductor device as a reference example.

In FIGS. 6 and 7, L1 illustrates the length of the lower electrode 21. L2 illustrates the length of the second semiconductor region 11. L3 illustrates the length of the upper electrode 22. L4 illustrates the length of the location at which the multiple ring-shaped regions 30 are located. L4+L5 illustrates the length of the termination region in the example. L6 illustrates the length of the lower electrode according to the reference example. L4+L7 illustrates the length of the termination region according to the reference example. The simulations were performed with the condition that the fourth semiconductor region 32 was located at the side surface of the first semiconductor region 1 in the example of FIG. 6, but the fourth semiconductor region 32 was not located at the side surface of the first semiconductor region 1 according to the reference example of FIG. 7.

Comparing FIGS. 6 and 7, it can be seen that the length L4+L5 of the termination region in the example can be less than the length L4+L7 of the termination region in the comparative example. In other words, based on the example, it is determined that the semiconductor device 100 according to the embodiment can maintain the breakdown voltage while reducing the termination region because the fourth semiconductor region 32 has a high impurity concentration and is located at the side surface of the first semiconductor region 1.

### Other Embodiments

Although embodiments are described above, the application of the technical idea of the disclosure is not limited to the configuration described above. For example, the fourth semiconductor region 32 that is continuous at the side surface of the semiconductor device 100 may have about the same impurity concentration as the third semiconductor region 12. Also, the multiple second ring-shaped regions 31 that are located in the termination region at the lower surface of the first semiconductor region 1 may have about the same impurity concentration as the third semiconductor region 12.

Although the semiconductor device 100 is implemented as a diode in the embodiments above, the semiconductor device 100 is not limited to such a configuration. For example, the semiconductor device 100 may be an IGBT (Insulated Gate Bipolar Transistor) that includes a p-layer as a collector layer at the lower surface side. Or, a MOSFET (Metal-Oxide-Semiconductor Field-Effect Transistor) that includes a trench gate electrode, a p-layer, and an n-layer at the upper surface side may be used. The type of the termination part is not limited to the embodiments above, and may be RESURF, a field plate, VLD (Variation of Lateral Doping), etc.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first semiconductor region including a central part and a termination region, the termination region surrounding the central part, the first semiconductor region being of a first conductivity type;
a second semiconductor region located at a lower part of the first semiconductor region at the central part, the second semiconductor region being of the first conductivity type, the second semiconductor region having a higher impurity concentration than the first semiconductor region;
a third semiconductor region located at an upper part of the first semiconductor region at the central part, the third semiconductor region being of a second conductivity type;
a first electrode located at a lower surface of the second semiconductor region at the central part, the first electrode being electrically connected with the second semiconductor region;
a second electrode located at an upper surface of the third semiconductor region, the second electrode being electrically connected with the third semiconductor region;
a ring-shaped region located in the termination region at the upper part of the first semiconductor region, the ring-shaped region surrounding the third semiconductor region, the ring-shaped region being of the second conductivity type; and
a fourth semiconductor region located at a side surface of the first semiconductor region, the fourth semiconductor region being of the second conductivity type.

2. The semiconductor device according to claim 1, wherein
an impurity concentration of the fourth semiconductor region is greater than an impurity concentration of the third semiconductor region.

3. The semiconductor device according to claim 1, wherein
an impurity concentration of the fourth semiconductor region is less than an impurity concentration of the third semiconductor region, and
a plurality of the fourth semiconductor regions is included.

4. The semiconductor device according to claim 1, further comprising:
a second ring-shaped region located in the termination region at a lower surface of the first semiconductor region,
the second ring-shaped region being of the second conductivity type.

5. The semiconductor device according to claim 4, wherein
a number of the second ring-shaped regions is less than a number of the ring-shaped regions.

6. The semiconductor device according to claim 4, wherein
an impurity concentration of the second ring-shaped regions is less than an impurity concentration of the third semiconductor region.

7. The semiconductor device according to claim 1, wherein
a length of the first electrode is less than a length of the second semiconductor region in a radial direction, and
the radial direction is from a center of the semiconductor device toward an outer perimeter of the semiconductor device when viewed in plan.

8. The semiconductor device according to claim 1, wherein
a plurality of the ring-shaped regions is located in the termination region at the upper part of the first semiconductor region.

9. The semiconductor device according to claim 8, wherein
a plurality of the ring-shaped regions has ring shapes surrounding the third semiconductor region with a prescribed spacing respectively interposed between the plurality of ring-shaped regions.

10. The semiconductor device according to claim 4, wherein
a plurality of the second ring-shaped regions is located in the termination region at the lower surface of the first semiconductor region.

11. The semiconductor device according to claim 10, wherein
a plurality of the second ring-shaped regions has ring shapes surrounding the second semiconductor region with a prescribed spacing respectively interposed between the plurality of second ring-shaped regions.

12. The semiconductor device according to claim 4, wherein
a plurality of the ring-shaped regions is located in the termination region at the upper part of the first semiconductor region,
a plurality of the second ring-shaped regions is located in the termination region at the lower surface of the first semiconductor region, and
a number of the second ring-shaped regions is less than a number of the ring-shaped regions.

13. The semiconductor device according to claim 12, wherein
a plurality of the ring-shaped regions has ring shapes surrounding the third semiconductor region with a prescribed spacing respectively interposed between the plurality of ring-shaped regions, and
a plurality of the second ring-shaped regions has ring shapes surrounding the second semiconductor region with a prescribed spacing respectively interposed between the plurality of second ring-shaped regions.

14. The semiconductor device according to claim 1, wherein
the fourth semiconductor region is continuous between an upper surface and a lower surface of the termination region.

15. The semiconductor device according to claim 1, further comprising:
an insulating part sealing an upper surface of the termination region.

16. The semiconductor device according to claim 15, wherein
the insulating part covers the ring-shaped region.

17. The semiconductor device according to claim 15, wherein
an upper surface of the second electrode at the central part is not covered with the insulating part.

18. The semiconductor device according to claim 1, wherein
the semiconductor device is a diode.

19. The semiconductor device according to claim 1, wherein
the semiconductor device is an Insulated Gate Bipolar Transistor (IGBT).

20. The semiconductor device according to claim 1, wherein
the semiconductor device is a Metal-Oxide-Semiconductor Field-Effect Transistor (MOSFET).
